(19) United States
(12) Patent Application Publication
(10) Pub. No.: US 2011/0216514 A1
(43) Pub. Date: Sep. 8, 2011

(54) COMBINED MULTILAYER CIRCUIT BOARD HAVING EMBEDDED COMPONENTS AND MANUFACTURING METHOD OF THE SAME

(75) Inventor: Jung-Chien Chang, Xinzhuang City (TW)

(73) Assignee: MUTUAL-TEK INDUSTRIES CO., LTD., Xinzhuang City (TW)

(21) Appl. No.: 13/034,404

(22) Filed: Feb. 24, 2011

(30) Foreign Application Priority Data
Mar. 3, 2010 (TW) 99106167

(51) Int. Cl. H05K 1/18; H05K 3/36

(52) U.S. Cl. 361/761; 29/830

(57) ABSTRACT

A combined multilayered circuit board is provided. The combined multilayered circuit board includes a plurality of multilayered circuit boards, at least one of the plurality circuit boards being formed with an embedded electronic component and an internal chamber receiving the embedded electronic component. The internal chamber is full of air. The combined multilayered circuit board further includes at least one glue layer interposed between each of the plurality of multiple circuit boards for bonding the plurality of multilayered circuit boards together.

### BACKGROUND OF THE INVENTION

### Related Applications

This application claims the right of priority based on Taiwan Patent Application No. 99106167, entitled “COMBINED MULTILAYER CIRCUIT BOARD HAVING EMBEDDED COMPONENTS AND MANUFACTURING METHOD OF THE SAME”, filed on Mar. 3, 2010. The entire contents of the aforementioned application is incorporated herein by reference.

### FIELD OF THE INVENTION

The invention is related to a combined multilayered circuit board and the method of manufacturing thereof, and more particularly to a combined multilayered circuit board having components embedded therein and the method of manufacturing thereof.

### DESCRIPTION OF THE PRIOR ART

In recent technology developments, people pay much attention to integrating various electronic components into circuit boards. The advancement of semiconductor technology has resulted in electronic products being smaller and more multi-functional, and thus more functions of the circuit boards, particularly to integrating more electronic components therein, is required. In order to fit this requirement, there is always a need to improve the structures of multilayered circuit boards and the manufacturing thereof.

### SUMMARY OF THE INVENTION

In light of the drawbacks of the prior arts, the present invention provides various combined multilayered circuit boards having electronic components embedded therein.

In one aspect, the present invention provides a combined multilayered circuit board, comprising: a plurality of multilayered circuit boards, at least one of the plurality multilayered circuit boards being formed with an embedded electronic component and an internal chamber receiving the embedded electronic component, wherein the internal chamber is full of air and closed with no communication to atmosphere; and at least one glue layer interposing between each of the plurality of multiple circuit boards for bonding the plurality of multilayered circuit boards together.

In another aspect, the present invention provides a combined multilayered circuit board, comprising a plurality of multilayered circuit boards, at least one of the plurality of multilayered circuit boards being formed with an embedded electronic component and an internal chamber receiving the embedded electronic component; at least one glue layer interposing between each of the plurality of multilayered circuit boards for bonding the plurality of multilayered circuit boards together; and at least one air outlet on an outer surface of the combined multilayered circuit board, the air outlet communicating with the internal chamber.

The present invention further provides methods of manufacturing the aforementioned combined multilayered circuit boards. The other aspects of the present invention, part of them will be described in the following description, part of them will be apparent from description, or can be known, from the execution of the present invention. The aspects of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE DRAWINGS

The foregoing aspects and many of the attendant advantages of the present invention will become more readily appreciated as the same becomes better understood by reference to the following detailed description, when taken in conjunction with the accompanying pictures, wherein:

FIGS. 1 to 4 are drawings, in cross-sectional view, illustrating one process of manufacturing a combined multilayered circuit board 400 in accordance with a first embodiment of the present invention;

FIG. 5 is a drawing, in cross-sectional view, illustrating one process of manufacturing a combined multilayered circuit board 500 in accordance with a second embodiment of the present invention;

FIG. 6 is a drawing, in cross-sectional view, illustrating one process of manufacturing a combined multilayered circuit board 600 in accordance with a third embodiment of the present invention;

FIG. 7 is a drawing, in cross-sectional view, illustrating one process of manufacturing a combined multilayered circuit board 700 in accordance with a fourth embodiment of the present invention; and

FIG. 8 is a drawing, in cross-sectional view, illustrating an enlarged structure of the conductive wire 23 in FIG. 2.

### DETAILED DESCRIPTION OF THE EMBODIMENTS

The preferred embodiment of the present invention is illustrated by referring the accompanying drawings. The similar elements in the accompanying drawings employ the same numeral references. It should be noted that in order to clearly illustrate the present invention, each element in the accompanying drawings are not drawn to scale as the actual object. Also, in order to avoid obscuring the content of the present invention, the conventional components, related material and related processing techniques are omitted in the followed description.

U.S. Pat. No. 7,603,771 entitled “METHOD OF MANUFACTURING A COMBINED MULTILAYER CIRCUIT BOARD HAVING EMBEDDED CHIPS,” is co-assigned to Assignee hereof. The entire contents of U.S. Pat. No. 7,603,771 are hereby incorporated herein by reference.

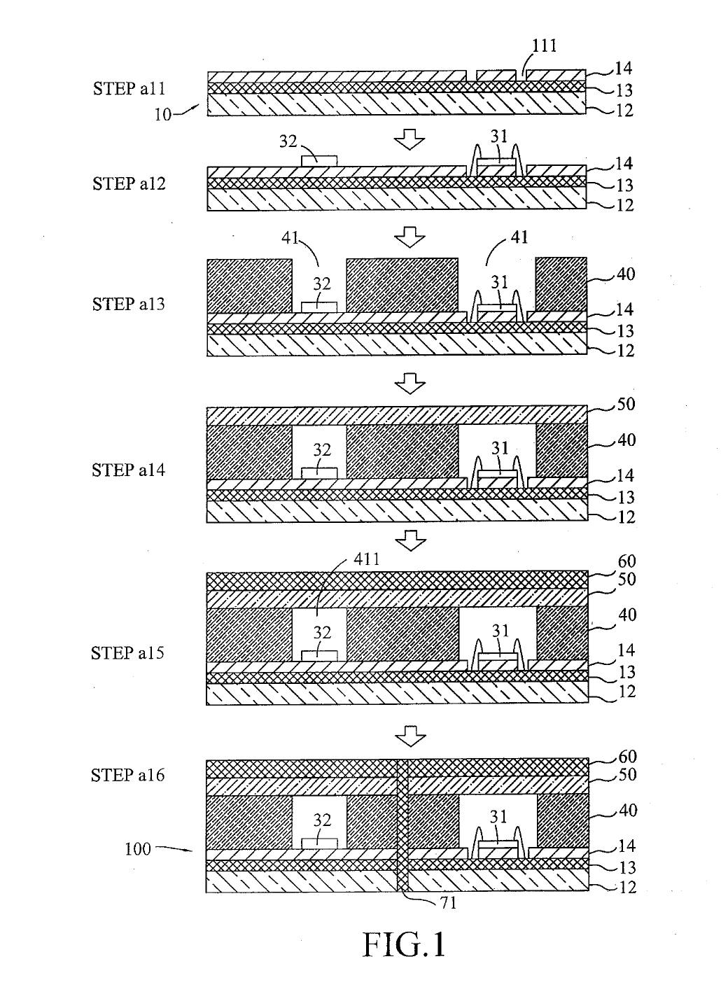

FIGS. 1 to 4 are drawings, in cross-sectional view, illustrating a combined multilayered circuit board 400 having embedded components and a manufacturing method thereof in accordance with a first embodiment of the present invention. Firstly, referring to FIG. 1, a multilayered circuit board 100 is fabricated by steps a11 to a16. In step all, a single-layer printed circuit board 10 is prepared. The single-layer printed circuit board 100 includes a FR4 substrate 12, a patterned conductive wiring layer 13, and an insulating coating 14. The insulating coating 14 has contact windows 111 exposing the underlying conductive wiring layer 13. The conductive wiring layer 13 positioned in the contact windows 111 can include nickel and/or gold plated contact pad (not shown). The FR4 substrate is a common term used in the printed circuit board industry and represents a substrate containing glass fiber and resin.

Referring to step a12 of FIG. 1, electronic components 31 and 32 are provided and placed on the printed circuit board 10. The electronic component 32 is a component not electrically connected to the conductive wiring layer 13; the electronic component 31 is a component electrically connected to the conductive wiring layer 13 through the contact windows 111. In this embodiment, the electrical connection is achieved by wire-bonding with the contact pad, but not limited thereto. Other suitable connection methods such as solder bonding are also included in the present invention. The electronic components 31 and 32 can be selected from magnetic device, quartz chip, vibration chip, MEMs chip, or other suitable components including mechanical electronic components. For the electronic component 31, adhesives (not shown) can be provided to fix the electronic component 31 on the insulating coating 14. The electronic component 32 can be fixed on the insulating coating 14 or simply placed on the insulating coating 14 without fixing. In this embodiment, the electronic component 32 is placed on the insulating coating 14 without fixing.

Referring to step a13 of FIG. 1, a dielectric frame 40 having a plurality of openings 41 is attached onto the printed circuit board 10. A general glue sheet having similar openings can be used for the attachment. The plurality of openings 41 correspond to the electronic components 31 and 32, so that the electronic components 31 and 32 are positioned within the openings 41, respectively. The opening 41 has an open end for receiving the electronic components 31 or 32, and the other end can be either open or closed. In this embodiment, the other end of the opening 41 is an open end, but not limited thereto.

Referring to step a14 of FIG. 1, a glue sheet 50 is provided and adhered onto the dielectric frame 40. The glue sheet 50 is a prepreg treated under vacuum thermal pressing and has no significant liquid glue. Such a glue sheet is also referred as non-flowing prepreg. Then, referring to step a15 of FIG. 1, a conductive layer 60 is thermally pressed onto the glue sheet 50. The conductive layer 60 can be a copper-containing layer, such as resin coated copper (RCC) containing no glass fiber, or other suitable material layer. When this step is performed, internal chambers 411 accommodating the electronic component 31 or 32 therein are formed. In this embodiment, when this step is completed, the closed internal chamber 411 is full of air and does not communicate with the atmosphere. By means of the non-flowing prepreg 50, the internal chamber 411 is free of liquid glue or has very little, if there is any. However, please note that if the other end of the opening 41 is a closed end, then the closed internal chamber 411 has been formed in step a13. Then, referring to step a16 of FIG. 1, a conductive via 71 is formed through the above-mentioned layers. The conductive via 71 electrically connects the conductive layer 60 to the conductive wiring layer 13.

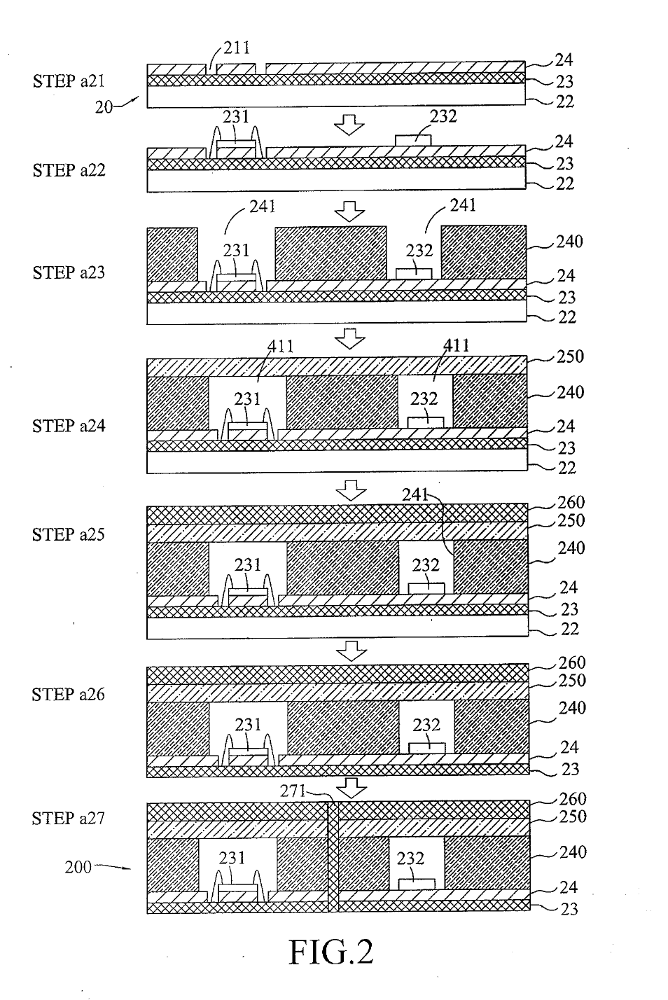

FIG. 2 illustrates another multilayered circuit board 200 that is fabricated by steps a21 to a27. The major difference between the multilayered circuit board 200 and the multilayered circuit board 100 is that the multilayered circuit board 200 uses a thin copper plate 22 as a base, and the thin copper plate 22 will be removed to expose preformed circuits or entire conductors during the manufacturing process. Except the difference, materials and technologies used for manufacturing the multilayered circuit board 200 can refer to those for the multilayered circuit board 100 as described above. Referring to FIG. 2, in step a21, a copper-based printed circuit board 20 is provided. The copper-based printed circuit board 20 includes a thin copper plate 22, a patterned conductive wiring layer 23, and an insulating coating 24. The patterned conductive wiring layer 23 can be a multilayered structure. As shown in the enlargement view of FIG. 8, the patterned conductive wiring layer 23 can include a lower wiring layer 23a, an upper wiring layer 23c, and a dielectric layer 23b interposed between the lower wiring layer 23a and the upper wiring layer 23c. The dielectric layer 23b includes inner vias 23d connecting the lower wiring layer 23a to the upper wiring layer 23c. The lower wiring layer 23a and the upper wiring layer 23c can be copper-plated layers, and the dielectric layer 23b can be a typical glue sheet. Referring to FIG. 2, a nickel layer serving as etching stop layer can be provided between the patterned conductive wiring layer 23 and the thin copper plate 22. The insulating coating 24 includes contact windows 211 to expose the underlying conductive wiring layer 23. The conductive wiring layer 23 positioned in the contact windows 211 can include nickel and/or gold plated contact pad (not shown). Referring to step a22 of FIG. 2, electronic components 231 and 232 are placed on the printed circuit board 20. The electronic components 231 and 232 are both fixed on the insulating coating 14. Referring to step a23 of FIG. 2, a dielectric frame 240 having a plurality of openings 241 is attached onto the printed circuit board 20. A general glue sheet having similar openings can be used for the attachment. The plurality of openings 241 correspond to the electronic components 231 and 232, so that the electronic components 231 and 232 are positioned within the openings 241, respectively. Referring to step a24, a glue sheet 250 is provided and adhered onto the dielectric frame 240. The glue sheet 250 can also be a non-flowing prepreg. Referring to step a25, a conductive layer 260 is thermally pressed onto the glue sheet 250. Then, referring to step a26, the thin copper plate 22 is removed by etching or any suitable methods. Referring to step a27, a conductive via 271 is formed through the above-mentioned layers. The conductive via 271 electrically connects the conductive layer 260 to the conductive wiring layer 23.

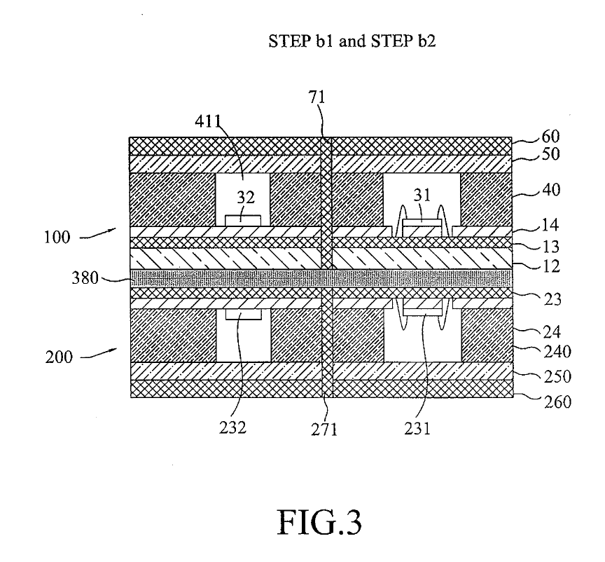

FIG. 3 illustrates steps of combining the multilayered circuit boards 100 and 200. These steps include step b1 of reversing the multilayered circuit board 200, so that the conductive wiring layer 23 faces the FR4 substrate 12 of the multilayered circuit board 100, and step b2 of providing a glue layer 380 between the conductive wiring layer 23 and the FR4 substrate 12 and performing a vacuum thermal press process to bond the multilayered circuit boards 100 and 200 together.

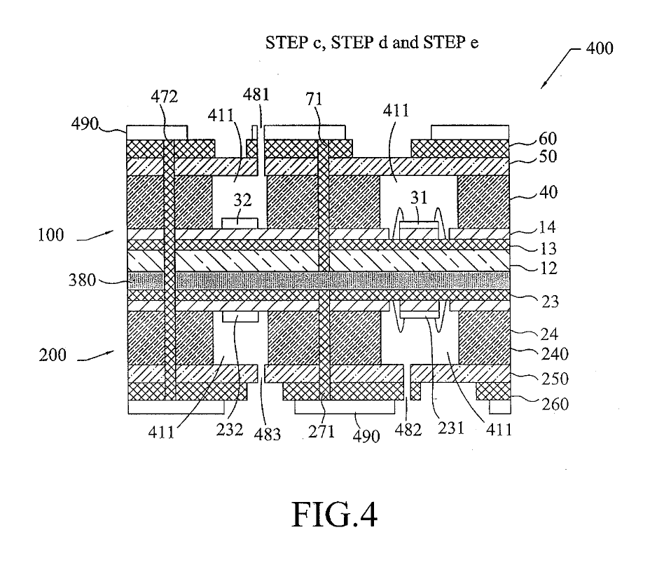

Referring to FIG. 4, steps of forming a combined multilayered circuit board 400 are performed. These steps include step c of forming an outer conductive via 472 through the multilayered circuit board 100, the glue layer 380, and the multilayered circuit board 200. The outer conductive via 472 electrically connects the conductive layer 60, the conductive wiring layer 13, the conductive wiring layer 23, and the conductive layer 260. Theses steps include step d of pattern-etching the conductive layers 60 and 260 and coating an insulating lacquer layer 490 to cover the patterned conductive layers 60 and 260. During the coating of the insulating lacquer layer 490, portions of the conductive layers 60 and 260 are conserved and exposed to serve as external contacts. These steps further include step e of forming air outlets 481, 482, and 483 passing through the combined multilayered circuit board 400 to communicate with the internal chambers 411. The air outlets are configured to communicate the internal chambers 411 with external environment for pressure balance to prevent board-blast in subsequent processes. The air outlet preferably has an inner diameter ranged between 0.05 mm and 0.2 mm. Conventional laser drilling or other suitable methods can form the air outlets. The locations of the air outlets can be varied, but preferably provided on the exposed outer surface of the combined multilayered circuit board 400. For example, in this embodiment, the air outlet 481 penetrates inwardly from the exposed insulating lacquer layer 490; the air outlet 482 penetrates inwardly from the exposed conductive layer 260; the air outlet 483 penetrates inwardly from the glue sheet 250. Moreover, in the embodiment, the internal chamber 411 having no air outlet is also provided. In this case, the internal chamber 411 is a closed environment full of air and does not communicate with the atmosphere. The internal chamber 411 having no air outlet is suitable for low chamber pressure and entire structure acceptable circumstances. Since the electronic component 32 is not fixed on the insulating coating 14 (which is considered as an inner surface of the internal chamber 411), if the combined multilayered circuit board 400 shakes, the electronic component 32 will move within the internal chamber 411 and sometimes make sounds due to the movement. In this embodiment, the closed and the atmosphere-isolated internal chamber 411 includes the electronic component 31 fixed on the insulating coating 14. In other embodiments, the closed and the atmosphere-isolated internal chamber 411 can also include the shakable electronic component 32 therein.

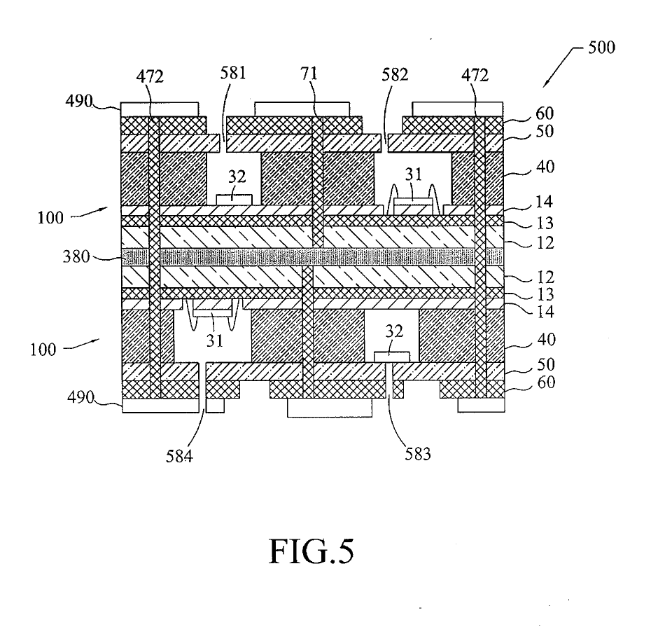

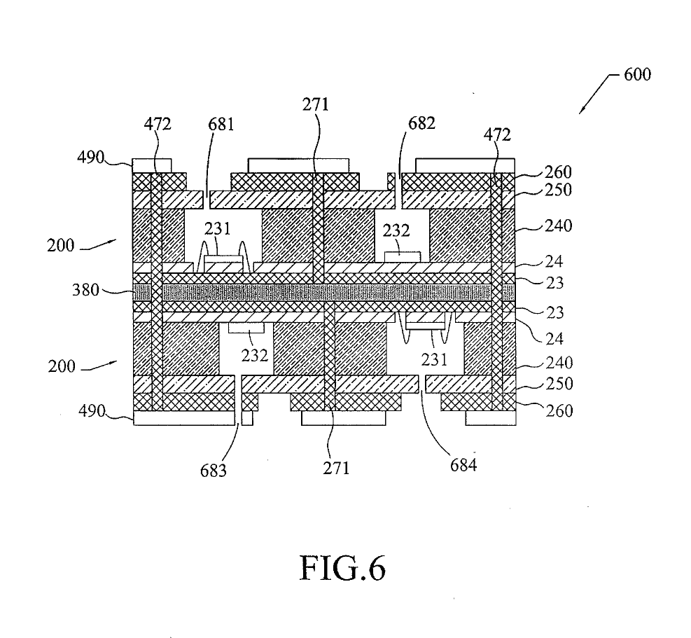

FIG. 5 illustrates a cross-sectional view of a combined multilayered circuit board 500 formed by combining two multilayered circuit boards 100 in accordance with a second embodiment of the present invention. The combined multilayered circuit board 500 has air outlets 581, 582, 583, and 584 at different locations. Please note that the electronic component 32 is not fixed on the insulating coating 14, so that when the lower multilayered circuit board 100 reveres, the electronic component 32 will fall on the glue sheet 50. FIG. 6 is a cross-sectional view of a combined multilayered circuit board 600 formed by combining two multilayered circuit boards 200 in accordance with the second embodiment of the present invention. The combined multilayered circuit board 600 has air outlets 681, 682, 683, and 684 at different locations. The multilayered circuit boards disclosed in the first, the second, and the third embodiments all have embedded components. The present invention also includes the embodiment of a combined multilayered circuit board formed by bonding a multilayered circuit board having embedded components and a multilayered circuit board without embedded component together.

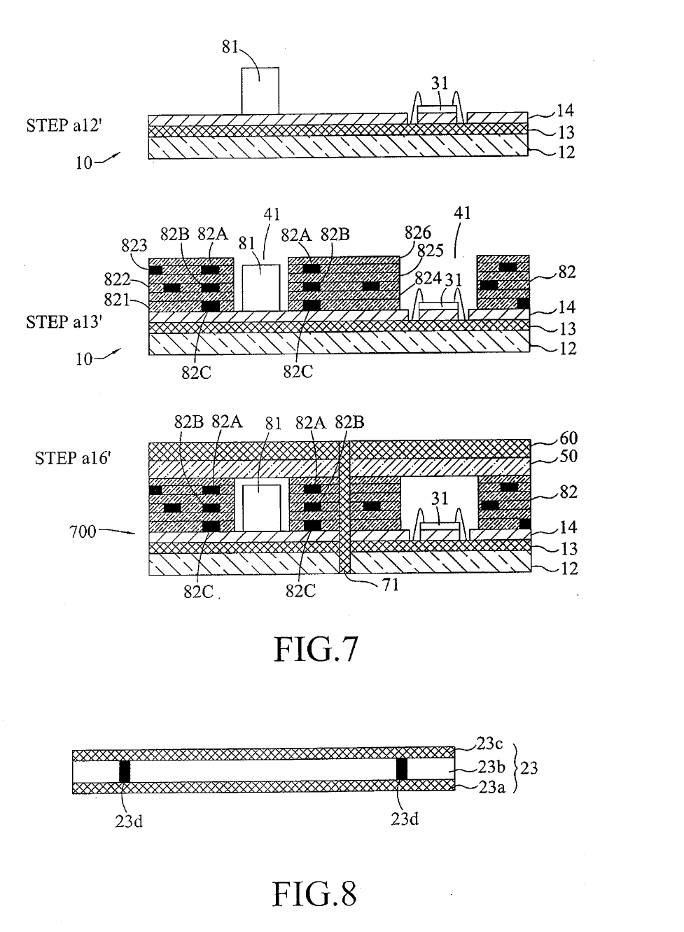

FIG. 7 is a drawing, in cross-sectional view, showing the manufacture process of a multilayered circuit board 700 in accordance with a fourth embodiment of the present invention. The fourth embodiment is similar to the first embodiment, but different in that a magnetic electronic component 81 substitutes the electronic component 32, and a multilayered frame 82 replaces the dielectric frame 40. For better understanding of the fourth embodiment, FIGS. 1 and 7 can be referred at the same time.

As shown in the drawings, step a12′ of FIG. 7 replaces step a12 of FIG. 1, wherein the magnetic electronic component 81 not electrically connected to the conductive wiring layer 13 is fixed on the insulating costing 14. Then, step a13′ of FIG. 7 replaces step a13 of FIG. 1, wherein the multilayered frame 82 having a plurality of openings 41 are attached onto the printed circuit board 10. The plurality of openings 41 correspond to locations for disposing the electronic component 31 and the magnetic electronic component 81, so that electronic component 31 and the magnetic electronic component 81 are positioned within the openings 41, respectively. In another embodiment, step a13′ can be performed prior to step a12′.

The multilayered frame of the present invention includes at least one wiring layer and one dielectric layer, and the fabrication method thereof can refer to conventional materials and manufacture methods. In an exemplarily embodiment of the multilayered frame 82 of the fourth embodiment, the multilayered frame 82 includes three wiring layers 821, 822, and 823 and three dielectric layers 824, 825, and 826. Each wiring layer can have various wiring patterns as required. For example, a wiring pattern of coiled circuits 82A, 82B, and 82C surrounding the magnetic electronic component 81 can be provided.

Then, referring to FIG. 1, the above steps a14, a15, and a16 can be performed, wherein the electronic component 32 is replaced with the magnetic electronic component 81, and the dielectric frame 40 is replaced with the multilayered frame 82. As such, the multilayered circuit board 700 in step a16′ of FIG. 7 can be obtained. Then the multilayered circuit board 700 of FIG. 7 can be applied to the combined multilayered circuit board of each embodiment as described above.

In view of the above preferred embodiments in combination of two multilayered circuit boards, one skilled person in the art should realize the execution of the present invention in combination of three or more than three multilayered circuit boards. While the present invention has been described with reference to the illustrative embodiments, these descriptions should not be construed in a limiting sense. Various modifications of the illustrative embodiment, as well as other embodiments of the invention, will be apparent upon reference to these descriptions. It is therefore contemplated that the appended claims will cover any such modifications or embodiments as falling within the true scope of the invention and its legal equivalents.

1. A combined multilayered circuit board, comprising:
a plurality of multilayered circuit boards, at least one of the plurality multilayered circuit boards being formed with an embedded electronic component and an internal chamber receiving the embedded electronic component, wherein the internal chamber is full of air and closed with no communication to atmosphere; and
at least one glue layer interposing between each of the plurality of multilayered circuit boards for bonding the plurality of multilayered circuit boards together.

2. The combined multilayered circuit board of claim 1, wherein the embedded electronic component is movable in the internal chamber by shaking the combined multilayered circuit board.

3. The combined multilayered circuit board of claim 1, wherein the combined multilayer circuit board further comprises a multilayered frame defining the internal chamber, the multilayered frame being formed with a coiled circuit surrounding the embedded electronic component.

4. A combined multilayered circuit board, comprising:
a plurality of multilayered circuit boards, at least one of the plurality of multilayered circuit boards being formed with an embedded electronic component and an internal chamber receiving the embedded electronic component;
at least one glue layer interposed between each of the plurality of multilayered circuit boards for bonding the plurality of multilayered circuit boards together; and
at least one air outlet on an outer surface of the combined multilayered circuit board, the air outlet communicating with the internal chamber.

5. The combined multilayered circuit board of claim 4, wherein the multilayered circuit board having the embedded electronic component further comprises a glue sheet on the internal chamber, and the outer surface includes a portion of the glue sheet where the air outlet passes through for communicating with the internal chamber.

6. The combined multilayered circuit board of claim 4, wherein the multilayered circuit board having the embedded electronic component further comprises a glue sheet and a conductive layer stacked on the internal chamber, and the outer surface includes a portion of the conductive layer where the air outlet passes through for communicating with the internal chamber.

7. The combined multilayered circuit board of claim 4, wherein the multilayered circuit board having the embedded electronic component further comprises a glue sheet, a conductive layer and an insulating lacquer layer stacked on the internal chamber, and the outer surface includes a portion of the insulating lacquer layer where the air outlet passes through for communicating with the internal chamber.

8. The combined multilayered circuit board of claim 4, wherein the air outlet is formed with a diameter ranged between 0.05 mm and 0.2 mm.

9. A method of manufacturing a combined multilayered circuit board, comprising:
providing a plurality of multilayered circuit boards, at least one of the plurality of multilayered circuit boards being formed with an embedded electronic component and an internal chamber receiving the embedded electronic component;
providing at least one glue layer interposed between each of the plurality of multilayered circuit boards;
pressing the glue layer with the plurality of multilayered circuit boards to bond the plurality of multilayered circuit boards together; and
forming at least one air outlet on an outer surface of the combined multilayered circuit board, the air outlet communicating with the internal chamber.

10. The method of manufacturing a combined multilayered circuit board of claim 9, wherein the multilayered circuit board having the embedded electronic component further comprises a glue sheet on the internal chamber, and the outer surface includes a portion of the glue sheet where the air outlet passes through for communicating with the internal chamber.

11. The method of manufacturing a combined multilayered circuit board of claim 9, wherein the multilayered circuit board having the embedded electronic component further comprises a glue sheet and a conductive layer stacked on the internal chamber, and the outer surface includes a portion of the conductive layer where the air outlet passes through for communicating with the internal chamber.

12. The method of manufacturing a combined multilayered circuit board of claim 9, wherein the multilayered circuit board having the embedded electronic component further comprises a glue sheet, a conductive layer and an insulating lacquer layer stacked on the internal chamber, and the outer surface includes a portion of the insulating lacquer layer where the air outlet passes through for communicating with the internal chamber.

13. The method of manufacturing a combined multilayered circuit board of claim 9, wherein the embedded electronic component is not fixed on an inner wall of the internal chamber.

14. The method of manufacturing a combined multilayered circuit board of claim 9, wherein the internal chamber is formed from a multilayered frame having a coiled circuit surrounding the embedded electronic component.

15. A method of manufacturing a combined multilayered circuit board, comprising:
providing a plurality of multilayered circuit boards, at least one of the plurality multilayered circuit boards being formed with an embedded electronic component and an internal chamber receiving the embedded electronic component, wherein the internal chamber is full of air and closed with no communication to atmosphere; and
providing at least one glue layer interposed between each of the plurality of multilayered circuit boards for bonding the plurality of multilayered circuit boards together.
